(19) United States
(12) Patent Application Publication
(10) Pub. No.: US 2008/0007914 A1
(43) Pub. Date: Jan. 10, 2008

(54) HEAT DISSIPATION DEVICE

(75) Inventors: Xue-Wen Peng, Shenzhen (CN); Bing Chen, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng (TW)

(21) Appl. No.: 11/309,650

(22) Filed: Sep. 5, 2006

(30) Foreign Application Priority Data
Jul. 7, 2006 (CN) 200610061556.7

(51) Int. Cl. H05K 7/20

(52) U.S. Cl. 361/700

(57) ABSTRACT

A heat dissipation device for removing heat from an electronic component includes separated first and second heat sinks and a plate-type heat pipe. The first heat sink has a side oriented to the second heat sink and defines a notch in the side thereof. The second heat sink defines a channel therein. The heat pipe includes a heat-absorber at one end thereof and a heat-exhauster at an opposite end thereof. The heat-absorber is attached into the notch and has a main surface facing the second heat sink. The heat-exhauster is fittingly engaged into the channel of the second heat sink to position the second heat sink thereon. The heat-exhauster dissipates heat transferred from the heat-absorber to the second heat sink.

### 1. FIELD OF THE INVENTION

The present invention relates to a heat dissipation device, and particularly to a combination of heat sinks and a heat pipe connecting the heat sinks. The heat dissipation device is particularly used for dissipating heat generated by a heat-generating chip of a computer periphery card.

### 2. DESCRIPTION OF RELATED ART

Continued development of electronics has enabled electronic components to perform more and more functions. Heat generated by the electronic components has thus increased enormously. Such heat can adversely affect the stability of the components. Measures must be taken to efficiently remove the heat from the component. Typically, a heat dissipation device is mounted on an electronic component to remove heat therefrom.

An example of a heat dissipation device used to remove heat from an electronic component comprises first and second heat sinks and a heat pipe connecting the first and second heat sinks. The electronic component is mounted on a first side of a circuit board. The first heat sink is attached onto the electronic component. The second heat sink is positioned at an opposite second side of the circuit board. The heat pipe goes round an edge of the circuit board and connects the first and second heat sinks. The heat pipe has a circular cross-section. Such a cylinder-like heat pipe cannot effectively transfer the heat from electronic component to the first heat sink and to the second heat sink. Furthermore, it is complicated and troublesome to intimately mount the cylinder-like heat pipe to the first and second heat sinks. Without an intimate contact between the heat pipe and the first and second heat sinks, the heat cannot be effectively transferred between the heat sinks and the heat pipe.

What is needed is an improved heat dissipation device which maximizes heat-dissipating efficiency. Furthermore, a heat pipe of the heat dissipation device can be intimately connected to heat sinks of the heat dissipation device in an easy manner.

### SUMMARY OF THE INVENTION

According to a preferred embodiment of the present invention, a heat dissipation device comprises separated first and second heat sinks and a plate-type heat pipe. The first heat sink has a side oriented to the second heat sink and defines a notch at the side thereof. The second heat sink defines a channel therein. The heat pipe comprises a heat-absorber at one end thereof and a heat-exhauster at an opposite end thereof. The heat-absorber is attached into the notch and has a main surface exposed to the second heat sink. The heat-exhauster is fittingly engaged into the channel of the second heat sink to position the second heat sink thereon. The heat-exhauster radiates heat transferred from the heat-absorber to the second heat sink. Heat generated by a heat-generating electronic component is firstly absorbed by the heat-absorber of the heat pipe and then transferred to the first heat sink and the heat-exhauster of the heat pipe from the heat-absorber.

Other advantages and novel features of the present invention will become more apparent from the following detailed description of preferred embodiment when taken in conjunction with the accompanying drawings, in which:

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present apparatus and method. Moreover, in the drawings, like reference numerals designate corresponding parts throughout the several views.

FIG. 1 is an exploded, isometric view of a heat dissipation device according to a preferred embodiment of the present invention;

FIG. 2 is an assembled view of FIG. 1; and

FIG. 3 is a side view of the heat dissipation device of FIG. 2, together with a fan mounted thereon.

### DETAILED DESCRIPTION OF THE INVENTION

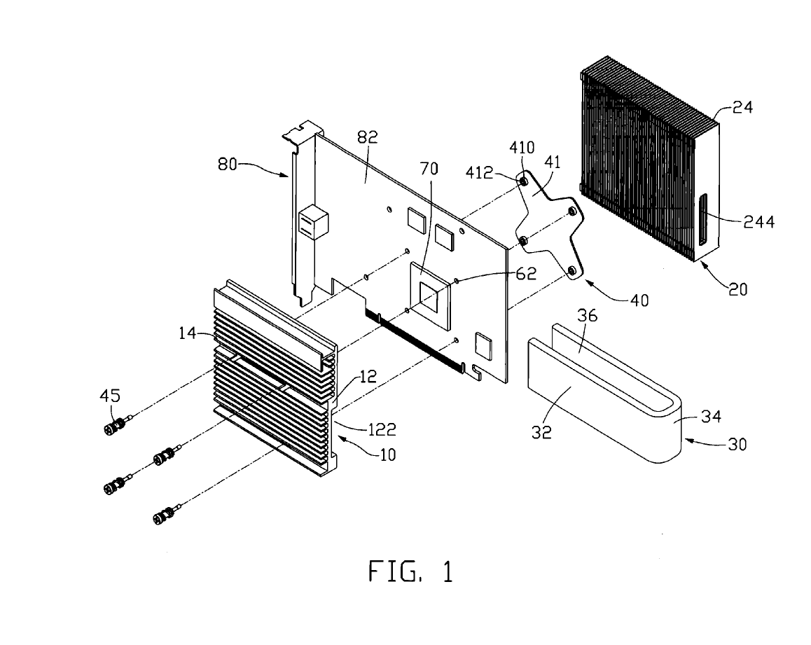

FIG. 1 shows a heat dissipation device in accordance with a preferred embodiment of the present invention, together with a circuit board 80 having an electronic component 70 mounted thereon. The circuit board 80 is for a computer periphery card (not labeled) which can be installed in a computer to connect a mother board of the computer with a periphery device of the computer, for example, a monitor. The computer periphery card according to the preferred embodiment is a VGA card.

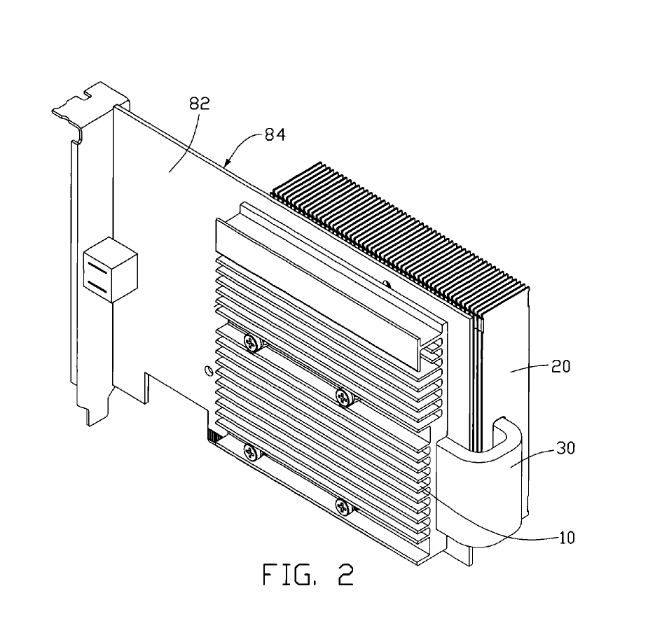

Referring to FIGS. 1-3, the circuit board 80 comprises opposite first and second sides 82, 84, parallel to each other. The electronic component 70 is mounted on the first side 82 of the circuit board 80. The electronic component 70 according to the preferred embodiment is a microprocessor unit of the VGA card. The circuit board 80 defines four apertures 62 extending through the first and second sides 82, 84 thereof. The apertures 62 are disposed around the electronic component 70 and near four corners (not labeled) of the electronic component 70.

The heat dissipation device comprises a first heat sink 10, a second heat sink 20, a heat pipe 30 and a back plate 40. The first heat sink 10 is disposed at the first side 82 of the circuit board 80 and separate from the electronic component 70 by the heat pipe 30. The second heat sink 20 is disposed at and parallel to the second side 84 of the circuit board 80. The back plate 40 abuts against the second side 84 of the circuit board 80 and disposed between the circuit board 80 and the second heat sink 20. The heat pipe 30 goes round an edge of the circuit board 80 and connects the first and second heat sinks 10, 20.

The first heat sink 10 comprises a base 12 and a plurality of parallel fins 14. The fins 14 extend from the base 12 in a direction away from the electronic component 70. A notch 122 is defined in a bottom of the base 12, opposite to the fins 14. The notch 122 has a rectangular configuration.

The second heat sink 20 comprises a plurality of parallel metallic flakes 24. The flakes 24 are interlocked together. Each flake 24 defines an opening (not labeled) therein. The openings of all of the flakes 24 are in alignment with each other and corporately define a channel 244 intersecting with the flakes after the flakes 24 are interlocked.

The heat pipe 30 is U-shaped, and plate-typed to have a substantially rectangular cross-section. The heat pipe 30 comprises a heat-absorber 32, a central connecter 34 and a heat-exhauster 36. Main surfaces (not labeled) of the heat-absorber 32 and the heat-exhauster 36 are parallel to the first and second sides 82, 84 of the circuit board 80. The heat-absorber 32 is inserted into the notch 122 of the first heat sink 10 and has an exposed main surface (not labeled) facing the first side 82 of the circuit board 80. The main surface is attached to the electronic component 70, whereby heat generated by the electronic component 70 is immediately absorbed by the heat-absorber 32. From the heat-absorber 32, a part of the heat is transferred to the first heat sink 10 for being dissipated to ambient air. Remaining part of the heat is transferred to the heat-exhauster 36 via a phase change of working fluid received in the heat pipe 30. The central connecter 34 connects the heat-absorber 32 to the heat-exhauster 36 to transfer the remaining part of the heat from the heat-absorber 32 to the heat-exhauster 36. The heat-exhauster 36 is fittingly engaged into the channel 244 of the second heat sink 20. The remaining part of the heat transferred to the heat-exhauster 36 is transferred to the flakes 24 for being dissipated to the ambient air.

The back plate 40 is cross-shaped and comprises four ears 41 outwardly extended. A post 410 extends perpendicularly from each ear 41 toward the second side 84 of the circuit board 80. The post 41 defines an inner threaded hole 412 therein for threadedly receiving a fixture 45 which has extended through the first heat sink 10 and the corresponding aperture 62 defined in the circuit board 80, to secure the first heat sink 10 to the circuit board 80 and thereby to render the heat-absorber 32 of the heat pipe 30 in intimate contact with the electronic component 70 and the first heat sink 10. In the preferred embodiment, the heat-absorber 32 can be soldered in the notch 122 and the heat-exhauster 36 can be soldered in the channel 244 in advance so that the first, second heat sinks 10, 20 and the heat pipe 30 form a subassembly before being assembled to the circuit board 80.

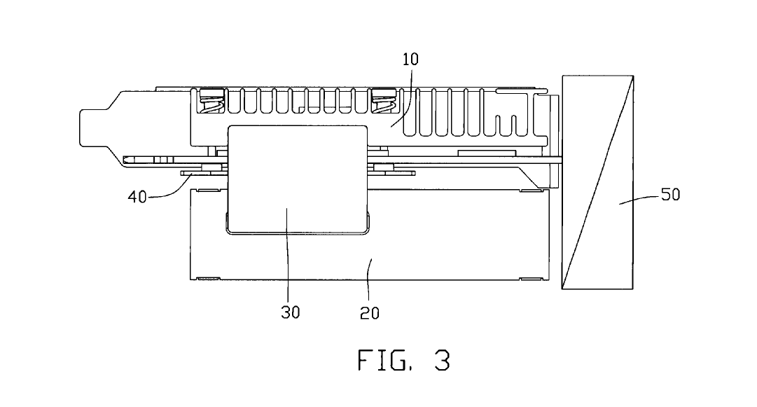

To improve air convection in the heat dissipation device, a fan 50 (see FIG. 3) is mounted to a top side of the combined heat dissipation device and circuit board 80 to help that the heat absorbed by the first and second heat sinks 10, 20 can be easily and quickly dissipated to the ambient air.

In the preferred embodiment, the heat-absorber 32 of the plate-type heat pipe 30 has a contacting area enough to overlay and intimately contact with the electronic component 70 to absorb the heat generated by the electronic component 70.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation device for removing heat from an electronic component, comprising:
separated first and second heat sinks, the first heat sink defining a notch in a bottom surface thereof, the second heat sink defining a channel therein; and
a heat pipe comprising a plate-type heat-absorber at one end thereof and a plate-type heat-exhauster at an opposite end thereof, the heat-absorber being inserted into the notch and having an exposed main surface adapted for contacting with the electronic component for absorbing heat therefrom, the heat-exhauster being fittingly engaged into the channel of the second heat sink to position the second heat sink thereon, the heat-exhauster transferring the heat to the second heat sink.

2. The heat dissipation device as described in claim 1, wherein the notch is opened to the second heat sink and the main surface of the heat-absorber is exposed to the second heat sink.

3. The heat dissipation device as described in claim 1, wherein the heat pipe is U-shaped and further comprises a connecter to connect the heat-absorber and the heat-exhauster.

4. The heat dissipation device as described in claim 1, wherein the first heat sink further comprises a plurality of parallel fins perpendicularly extending from the base in a direction away from the said side of the base.

5. The heat dissipation device as described in claim 1, wherein the second heat sink comprises a plurality of interlocked metallic flakes, and the channel intersects with the flakes.

6. An electronic combination, comprising:
a circuit board comprises opposite first and second sides, and having an electronic component mounted on the first side,
a first heat sink disposed at the first side of the circuit board;
a second heat sink disposed at the second side of the circuit board; and
a heat pipe connecting the first and second heat sinks, the heat pipe comprising a plate-type heat-absorber overlaying and intimately contacting the electronic component.

7. The electronic combination as described in claim 6, further comprising a back plate and a plurality of fixtures cooperatively with the back plate to secure the first heat sink to the circuit board.

8. The electronic combination as described in claim 7, wherein the circuit board defines a plurality of apertures around the electronic component, and wherein the back plate comprises a plurality of posts each defining a hole in alignment with the apertures.

9. The electronic combination as described in claim 8, wherein the fixtures extend through the first heat sink, the apertures of the circuit board, and further engage in the holes.

10. The electronic combination as described in claim 7, wherein the back plate abuts against the circuit board and is disposed between the circuit board and the second heat sink.

11. The electronic combination as described in claim 6, wherein the first heat sink defines a notch in a surface thereof facing the circuit board, and wherein the notch receives the heat-absorber therein.

12. The electronic combination as described in claim 6, wherein the first heat sink is separate from the electronic component by the heat-absorber of the heat pipe.

13. The electronic combination as described in claim 6, wherein the second heat sink comprises a plurality of interlocked metallic flakes and defines a channel intersecting with the flakes, and wherein the heat pipe comprises a heat-exhauster fitly engaged into the channel to position the second heat sink thereon.

14. The electronic combination as described in claim 6 further comprising a fan mounted on a side of the circuit board for generating an airflow through the first and second heat sinks.

15. A computer peripheral card comprising:
a circuit board having a first side and an opposite second side;
a processor mounted on the first side of the circuit board;
a first heat sink mounted on the first side of the circuit board;
a second heat sink mounted on the second side of the circuit board; and
a heat pipe having a first end thermally interconnecting the processor and the first heat sink and a second end thermally connecting with the second heat sink, wherein heat generated by the processor is firstly absorbed by the first end of the heat pipe and then transferred to the first heat sink via the first end of the heat pipe and the second heat sink via the second end of the heat pipe.

16. The computer peripheral card as described in claim 15, wherein the heat pipe has a U-shaped configuration with a rectangular cross-section.

17. The computer peripheral card as described in claim 16 further comprising a back plate on the second side of the circuit board, fixtures extending through the first heat sink and the circuit board to engage with the back plate thereby combining the first heat sink and the circuit board together.

18. The computer peripheral card as described in claim 17 further comprising a fan mounted on an edge of the circuit board, for generating an airflow through the first and second heat sinks.
